(19) United States
(12) Patent Application Publication
(10) Pub. No.: US 2018/0358530 A1
(43) Pub. Date: Dec. 13, 2018

(54) HEAT ABSORBING ELEMENT, SEMICONDUCTOR DEVICE PROVIDED WITH SAME, AND METHOD FOR MANUFACTURING HEAT ABSORBING ELEMENT

(71) Applicant: MAZDA MOTOR CORPORATION, Hiroshima (JP)

(72) Inventors: Shinichiro KUROKI, Hiroshima (JP); Yutaka FURUBAYASHI, Hiroshima (JP); Takafumi TANEHIRA, Hiroshima-shi, Hiroshima (JP); Nobuhide SEO, Hiroshima-shi, Hiroshima (JP); Kei YONEMORI, Hiroshima-shi, Hiroshima (JP)

(73) Assignee: MAZDA MOTOR CORPORATION, Hiroshima (JP)

(21) Appl. No.: 15/745,626

(22) PCT Filed: Jun. 28, 2016
(86) PCT No.: PCT/JP2016/003103

§ 371 Date: Jan. 17, 2018

(30) Foreign Application Priority Data
Jul. 23, 2015 (JP) 2015-145621

(51) Int. Cl. H01L 35/22; H01L 35/30; H01L 35/32; H01L 35/34

(52) U.S. Cl. CPC H01L 35/22; H01L 35/30; H01L 35/16; H01L 35/34; H01L 35/32

(57) ABSTRACT

A heat absorbing element 20 of a thin-film Peltier type is thermally connected with a surface of a semiconductor element body portion 10 through a heat conducting layer 15 which is an electrical insulator. The heat absorbing element 20 is comprised of a substance having a bulk thermal conductivity of 50 W/mK or more and a Seebeck coefficient of 300 μV/K or more.

### TECHNICAL FIELD

The present invention relates to a heat absorbing element, a semiconductor device provided with the same, and a method for manufacturing a heat absorbing element.

### BACKGROUND ART

A recent power semiconductor device of the known art includes a cooling element such as a Peltier element to enhance heat dissipation from the power semiconductor device to its outside.

A typical power semiconductor device includes a power semiconductor element having a heat generating portion and a Peltier element, which are made close to each other to be modularized (see, e.g., Patent Document 1). Another known power semiconductor element includes a heat generating portion in which (specifically, in a region between trench gate electrodes,) a buried metal for heat dissipation is arranged, and a Peltier element is provided on the buried metal for heat dissipation (see, e.g., Patent Document 2).

### CITATION LIST

### Patent Documents

PATENT DOCUMENT 1: Japanese Unexamined Patent Publication No. 2008-235834

PATENT DOCUMENT 2: Japanese Unexamined Patent Publication No. 2007-227615

### SUMMARY

### Technical Problem

In the above conventional techniques, the power semiconductor element includes the heat generating portion and the Peltier element, which are made close to each other. However, the thermal resistance of the contact portion therebetween is large, and instantaneous cooling after heat generation of the power semiconductor element cannot be achieved. Thus, currently, a redundant, high-cost thermal design has to be employed to prepare for a calorific value obtained at the time of application of the maximum load to the power semiconductor element.

In addition, a method for manufacturing a thin-film Peltier element formed on a semiconductor element has not been established.

In view of the foregoing, it is an object of the present invention to provide a thin-film heat absorbing element formed on a semiconductor element wherein the thermal resistance between the semiconductor element and the heat absorbing element is reduced, and to establish a method for manufacturing the heat absorbing element.

### Solution to the Problem

To achieve the above object, the present invention provides a heat absorbing element of a thin-film Peltier type formed on a semiconductor element.

Specifically, the present invention is directed to a heat absorbing element, a semiconductor device having the same, and a method for manufacturing the heat absorbing element. The following solution is provided.

Specifically, the first aspect of the present invention is directed to a heat absorbing element of a thin-film Peltier type thermally connected with a surface of a semiconductor element through an electrical insulator. The heat absorbing element is comprised of a substance having a bulk thermal conductivity of 50 W/mK or more and a Seebeck coefficient of 300 μV/K or more.

This can provide reduction in thermal resistance between the semiconductor element and the heat absorbing element, and enhance the heat dissipation of the semiconductor element.

A second aspect of the present invention is an embodiment of the first aspect. In the second aspect, the substance is any one of silicon (Si), silicon carbide (SiC), gallium nitride (GaN), aluminum nitride (AlN), boron nitride (BN), or diamond (C).

This can reliably achieve the formation of a highly efficient heat absorbing element.

A third aspect of the present invention is an embodiment of the first aspect. In the third aspect, the substance is silicon.

This is preferable because of compatibility with a semiconductor manufacturing process.

A forth aspect of the present invention is an embodiment of any one of the first to third aspects. In the fourth aspect, the substance constitutes a p-type or n-type semiconductor layer, and the p-type semiconductor layer and the n-type semiconductor layer are arranged parallel to the semiconductor element and the electrical insulator.

This can reliably achieve manufacturing of the Peltier element, which is a heat absorbing element of a thin-film type. In addition, the contact area between the semiconductor element and the electrical insulator can be increased, and the thus the efficiency of heat adsorbing effect (heat dissipation effect) is improved.

A fifth aspect of the present invention is an embodiment of any one of the first to fourth aspects. In the fifth aspect, the heat absorbing element is directly formed on and thermally coupled with a heat exhaust side of the semiconductor element.

This allows the heat absorbing element to have an improved heat absorbing efficiency, and the semiconductor element to provide an excellent heat dissipation effect.

A sixth aspect of the present invention is an embodiment of any one of the first to fifth aspects. In the sixth aspect, the heat absorbing element covers 10% or more of an area of a heat source in the semiconductor element.

As long as 10% or more of the area of the heat source is covered in this manner, the semiconductor element can provide an improved heat dissipation effect.

The seventh aspect of the present invention is directed to a semiconductor device, comprising the heat absorbing element according to any one of the first to sixth aspects.

The semiconductor device of this invention includes the heat absorbing element of the present invention. Thus, the semiconductor element can perform improved heat dissipation.

An eight aspect of the present invention is an embodiment of the seventh aspect. In the eighth aspect, the semiconductor element is a power semiconductor element.

This allows a power semiconductor element having a high temperature during operation to perform improved heat dissipation.

A ninth aspect of the present invention is an embodiment of the seventh aspect. In the ninth aspect, the semiconductor element is a SiC power semiconductor element of which a material is silicon carbide.

Accordingly, a SiC power semiconductor element having a high withstand voltage and a low on-resistance and being able to perform high speed operation can perform improved heat dissipation.

A tenth aspect of the present invention is directed to a method for manufacturing a heat absorbing element of a thin-film Peltier type thermally connected with a surface of a semiconductor element through an electrical insulator. The method includes: forming a lower metal film, a first conductivity type semiconductor layer, and a first metal sacrificial film in order on the semiconductor element through the electrical insulator; forming a first metal mask film for patterning the first conductivity type semiconductor layer from the first metal sacrificial film, and using the first metal mask film formed, patterning the first conductivity type semiconductor layer so as to form a plurality of first conductivity type semiconductor blocks from the first conductivity type semiconductor layer; forming a second conductivity type semiconductor layer and a second metal sacrificial film in order on the lower metal film including the first conductivity type semiconductor block; forming a second metal mask film for patterning the second conductivity type semiconductor layer from the second metal sacrificial film, and using the second metal mask film formed, patterning the second conductivity type semiconductor layer so as to form a plurality of second conductivity type semiconductor blocks from the second conductivity type semiconductor layer; selectively etching, by a lithography method, an electrode formation region of the semiconductor element in the lower metal film so as to expose the semiconductor element; selectively etching, by a lithography method, a portion between the first conductivity type semiconductor block and the second conductivity type semiconductor block in the lower metal film so as to form a plurality of lower electrodes from the lower metal film; selectively forming an insulation film on a portion between the semiconductor blocks and on a portion between the lower electrodes, followed by forming an upper metal film on the semiconductor blocks and on an exposed portion of the semiconductor element; and selectively etching, by a lithography method, the upper metal film so as to form an upper electrode and an electrode of the semiconductor element from the upper metal film.

According to this method, the heat absorbing element can be formed through: etching of the lower metal film to serve as the lower electrode of the heat absorbing element, the first conductivity type semiconductor layer, and the second conductivity type semiconductor layer that are formed on or above the semiconductor element via the electrical insulator; and etching of the upper metal film to serve as the upper electrode of the heat absorbing element and the electrode of the semiconductor element.

An eleventh aspect of the present invention is an embodiment of the tenth aspect. In the eleventh aspect, the first conductivity type semiconductor layer and the second conductivity type semiconductor layer are each comprised of any one of silicon (Si), silicon carbide (SiC), gallium nitride (GaN), aluminum nitride (AlN), boron nitride (BN), or diamond (C).

This can reliably achieve the formation of a highly efficient heat absorbing element.

A twelfth aspect of the present invention is an embodiment of the tenth or eleventh aspect. In the twelfth aspect, the lower metal film, the first metal sacrificial film, the second metal sacrificial film, and the upper metal film are comprised of nickel, and at least one of the lower metal film, the first metal sacrificial film, the second metal sacrificial film, or the upper metal film is patterned by wet-etching with an etchant which is a mixture (hydrochloric acid hydrogen peroxide solution) of concentrated hydrochloric acid, concentrated hydrogen peroxide solution, and pure water.

This allows the nickel film to be etched without degradation of the resist.

A thirteenth aspect of the present invention is an embodiment of any one of the tenth to twelfth aspects. In the thirteenth aspect, the first metal sacrificial film and the second metal sacrificial film are comprised of nickel, the first conductivity type semiconductor layer and the second conductivity type semiconductor layer are comprised of silicon, and the forming the first conductivity type semiconductor blocks and the forming the second conductivity type semiconductor blocks are carried out by dry-etching with chlorine and hydrogen bromide.

This allows the first metal sacrificial film as a first metal mask film comprised of nickel and the second metal sacrificial film as a second metal mask film comprised of nickel to be used as hard masks in etching for forming the first conductivity type semiconductor block and the second conductivity type semiconductor block from the first conductivity type semiconductor layer and the second conductivity type semiconductor layer comprised of silicon.

A fourteenth aspect of the present invention is an embodiment of any one of the tenth to thirteenth aspects. In the fourteenth aspect, the semiconductor element is a power semiconductor element.

This allows a power semiconductor element having a high temperature during operation to perform improved heat dissipation.

A fifteenth aspect of the present invention is an embodiment of any one of the tenth to thirteenth aspects. In the fifteenth aspect, the semiconductor element is a SiC power semiconductor element of which a material is silicon carbide.

Accordingly, a SiC power semiconductor element having a high withstand voltage and a low on-resistance and being able to perform high speed operation can perform improved heat dissipation.

### Advantages of the Invention

The present invention can provide a significant reduction in the thermal resistance between the semiconductor element and the heat absorbing element, and also achieve reliable manufacturing of the heat absorbing element of a thin-film type on the surface of semiconductor element.

### BRIEF DESCRIPTION OF THE DRAWINGS

FIG. 1 is a cross-sectional view of a main part of a semiconductor device of a first embodiment of the present invention.

FIG. 2 is a cross-sectional view of a main part of a semiconductor device of a first variation of the first embodiment of the present invention.

FIG. 3 is a cross-sectional view of a main part of a semiconductor device of a second variation of the first embodiment of the present invention.

FIG. 4 is a cross-sectional view of a main part of a semiconductor device of a second embodiment of the present invention.

FIG. 5 is a cross-sectional view showing one process step representing a main part of a method for manufacturing a semiconductor device of a third embodiment of the present invention.

FIG. 6 is a cross-sectional view showing one process step representing the main part of the method for manufacturing the semiconductor device of the third embodiment of the present invention.

FIG. 7 is a cross-sectional view showing one process step representing the main part of the method for manufacturing the semiconductor device of the third embodiment of the present invention.

FIG. 8 is a cross-sectional view showing one process step representing the main part of the method for manufacturing the semiconductor device of the third embodiment of the present invention.

FIG. 9 is a cross-sectional view showing one process step representing the main part of the method for manufacturing the semiconductor device of the third embodiment of the present invention.

FIG. 10 is a cross-sectional view showing one process step representing the main part of the method for manufacturing the semiconductor device of the third embodiment of the present invention.

FIG. 11 is a cross-sectional view showing one process step representing the main part of the method for manufacturing the semiconductor device of the third embodiment of the present invention.

FIG. 12 is a cross-sectional view showing one process step representing the main part of the method for manufacturing the semiconductor device of the third embodiment of the present invention.

FIG. 13 is a cross-sectional view showing one process step representing the main part of the method for manufacturing the semiconductor device of the third embodiment of the present invention.

FIG. 14 is a cross-sectional view showing one process step representing the main part of the method for manufacturing the semiconductor device of the third embodiment of the present invention.

FIG. 15 is a cross-sectional view showing one process step representing the main part of the method for manufacturing the semiconductor device of the third embodiment of the present invention.

FIG. 16 is a cross-sectional view showing one process step representing the main part of the method for manufacturing the semiconductor device of the third embodiment of the present invention.

FIG. 17 is a cross-sectional view showing one process step representing the main part of the method for manufacturing the semiconductor device of the third embodiment of the present invention.

FIG. 18 is a cross-sectional view showing one process step representing the main part of the method for manufacturing the semiconductor device of the third embodiment of the present invention.

FIG. 19 is a schematic view of a heat absorbing element of one example of the present invention.

FIG. 20 illustrates graphs for showing driving current dependence by comparison between the total amount of heat transfer of a Peltier element of one example of which the lower limit values of a Seebeck coefficient and a thermal conductivity are set and the total amount of heat transfer of a typical Peltier element with bismuth tellurium.

FIG. 21 illustrates graphs for showing driving current dependence of the total amount of heat transfer of each material usable for the Peltier element of one example.

### DESCRIPTION OF EMBODIMENTS

Embodiments of the present invention will be described in detail below with reference to the drawings. The following embodiments are merely exemplary ones in nature, and are not intended to limit the scope, applications, or use of the invention.

### First Embodiment

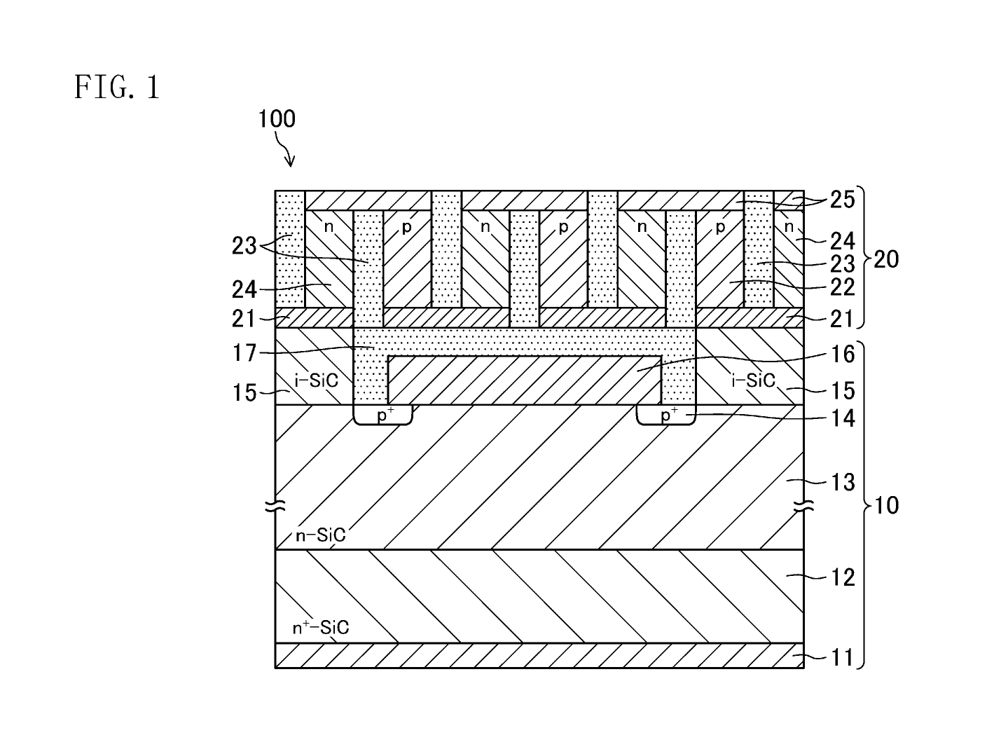

FIG. 1 illustrates a cross-sectional configuration of a main part of a semiconductor device of a first embodiment of the present invention.

As illustrated in FIG. 1, the semiconductor device 100 of the embodiment includes a semiconductor element body portion 10 and a heat absorbing element portion 20 integrally formed on the semiconductor element body portion 10.

The semiconductor element body portion 10 is a schottky-barrier diode (hereinafter also abbreviated as a SBD). For a semiconductor of the diode, silicon carbide (SiC) can be used for example. Here, the semiconductor element body portion 10 includes, e.g., a bulk layer (a contact layer) 12 comprised of n⁺-type SiC; a drift layer 13 regulating withstand voltage and comprised of n-type SiC epitaxially grown on the bulk layer 12; a heat conducting layer 15 having insulation properties and comprised of i-type SiC epitaxially grown on the drift layer 13; an anode electrode 11 formed on a surface (a back surface) of the bulk layer 12, the surface being opposite to the drift layer 13; and a plurality of cathode electrodes 16 formed selectively on partial regions of a surface (a front surface) of the drift layer 13, the surface being opposite to the bulk layer 12, and the partial regions (electrode formation regions) being exposed from the heat conducting layer 15. FIG. 1 illustrates one of the plurality of cathode electrodes 16 for convenience, whereas the plurality of cathode electrodes 16 having the same shape are arranged laterally (two-dimensionally) at predetermined intervals. Here, for example, the anode electrode 11 is comprised of nickel silicide (NiSix), and the cathode electrode 16 is comprised of nickel (Ni). The drift layer 13 includes an upper portion having designated portions each facing a peripheral portion of the associated cathode electrode 16. Each designated portion constitutes a p⁺ region 14 for improving withstand voltage of the SBD. Note that the p⁺ region 14 does not necessarily have to be provided in the SBD, and may be suitably provided, if necessary, depending on, e.g., use of the semiconductor device 100.

The material for the anode electrode 11 is not limited to nickel silicide, and may be a metal or metal silicide that can establish favorable Ohmic contact with n-type SiC. The material for the cathode electrode 16 is not limited to nickel, and may be a metal that can establish favorable Schottky contact with n-type SiC.

On the other hand, the heat absorbing element portion 20 is a thin-film Peltier element. The Peltier element includes p-type silicon layers 22 and n-type silicon layers 24. The p-type silicon layers 22 and the n-type silicon layers 24 are arranged alternately in a dotted (island) manner on the semiconductor element body portion 10. The Peltier element also includes lower electrodes 21 and upper electrodes 25. The lower electrodes 21 are arranged below the silicon layers 22, 24, and the upper electrodes 25 are arranged above the silicon layers 22, 24, so that a current passes though the silicon layers 22, 24 alternately. Here, the lower electrodes 21 and the upper electrodes 25 can be comprised of nickel (Ni) for example. Insulation films 23 are filled and formed between the p-type silicon layer 22 and the n-type silicon layer 24, between the lower electrodes 21, and between the upper electrodes 25. The insulation films 23 are comprised of, e.g., silicon oxide (SiO₂).

The heat absorbing element portion 20 includes the lower electrodes 21 which are directly connected to, i.e., thermally coupled to the heat conducting layer 15 having insulation properties, comprised of i-type SiC, and exposed from a surface of the semiconductor element body portion 10. In a region above each cathode electrode 16, the heat absorbing element portion 20 is connected to an insulation film 17 filled in an ambient region of the cathode electrode 16 and comprised of, e.g., silicon oxide (SiO₂). As such, the p-type silicon layers 22 and the n-type silicon layers 24 are arranged parallel to the heat conducting layer 15 and the insulation film 17 of the semiconductor element body portion 10.

The heat absorbing element portion 20 is comprised of a semiconductor of silicon (Si). Alternatively, the heat absorbing element portion 20 can be comprised of a semiconductor material having a bulk thermal conductivity of 50 W/mK or more and a Seebeck coefficient of 300 μV/K or more similarly to silicon (Si). Examples of such a semiconductor material include silicon carbide (SiC), gallium nitride (GaN), aluminum nitride (AlN), boron nitride (BN), and diamond (C). From these materials, a highly efficient Peltier element can be fabricated.

The lower electrode 21 and the upper electrode 25 are comprised of Nickel (Ni). Alternatively, the lower electrode 21 and the upper electrode 25 can be comprised of titanium (Ti), aluminum (Al), tin (Sn), molybdenum (Mo), copper (Cu), or gold (Au).

In this embodiment, the lower electrode 21 is a Ni film having a thickness of, e.g., 450 nm. The p-type silicon layer 22 and the n-type silicon layer 24 have a thickness of, e.g., 1.2 μm. The upper electrode 25 is a Ni film having a thickness of, e.g., 200 nm. As such, the body thickness of the heat absorbing element portion 20 of the semiconductor device 100 of this embodiment is 1.85 μm, i.e., within 2 μm.

As long as the heat absorbing element portion 20 covers 10% or more of the area of a heat source in the semiconductor element body portion 10, the advantage of the present invention can be reliably obtained. Here, the heat source of the semiconductor element body portion 10 mainly refers to the sum of regions in plan view of a region including opposing portions of the plurality of cathode electrodes 16 and the anode electrode 11 in the drift layer 13.

—Advantage—

As described above, according to this embodiment, the heat absorbing element portion 20 of the thin-film Peltier type is integrally formed on the semiconductor element body portion 10 configured as a SBD. Then, the heat absorbing element portion 20 includes the lower electrode 21 directly connected to the heat conducting layer 15 having insulation properties and being the epitaxial growth part of the semiconductor element body portion 10. This provides a significant reduction in the thermal resistance between the semiconductor element body portion 10 and the heat absorbing element portion 20.

(First Variation of First Embodiment)

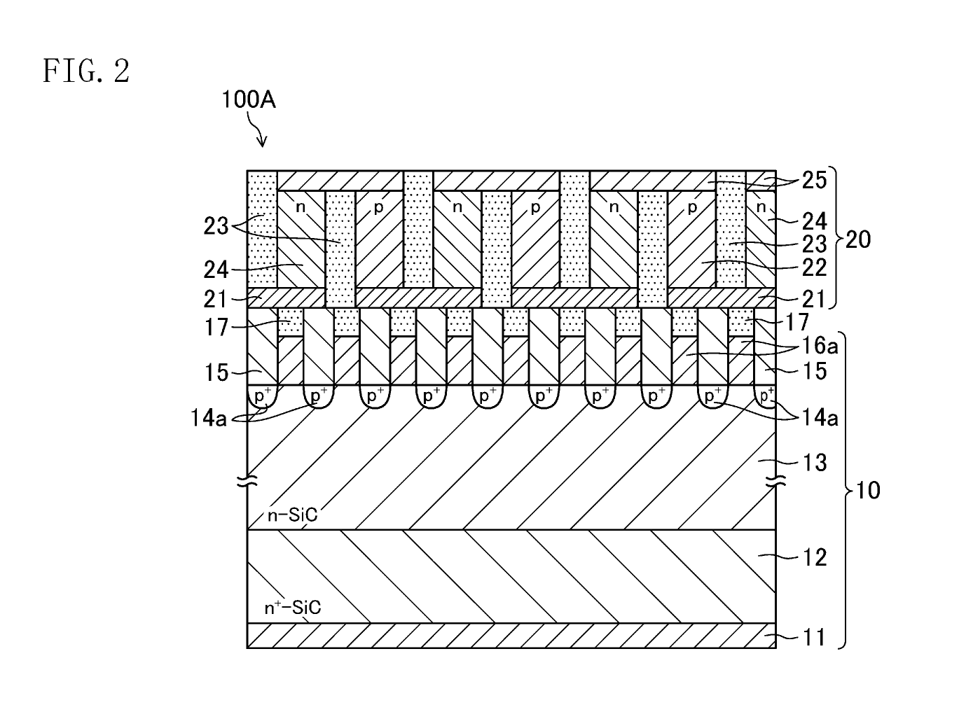

FIG. 2 illustrates a cross-sectional configuration of a main part of a semiconductor device of a first variation of the first embodiment of the present invention.

A semiconductor device 100A of the first variation includes a semiconductor element body portion 10 different from that of the first embodiment, but, except for this point, includes the same configurations as those of the first embodiment. In the following descriptions, the same components as those of the first embodiment are denoted with the same reference characters.

As illustrated in FIG. 2, the semiconductor element body portion 10 of the semiconductor device 100A of this variation is a Junction Barrier Schottky diode (hereinafter also abbreviated as a JBS diode). The JBS diode constituting the semiconductor element body portion 10 includes a heat conducting layer 15 having insulation properties and comprised of i-type SiC. The heat conducting layer 15 is provided with a plurality of gap portions spaced apart from each other. These gap portions are filled with, e.g., nickel (Ni) to provide a plurality of cathode electrodes 16a.

The segments of the heat conducting layer 15 each include a lower portion provided in the drift layer 13, the lower portion being a p⁺ region 14a to improve withstand voltage of the semiconductor element body portion 10.

Note that the heat absorbing element portion 20 includes the configurations equivalent to those of the first embodiment.

Thus, not only the thickness, etc. of the materials described in the first embodiment, but also the other applicable materials can be applied to this variation.

(Second Variation of First Embodiment)

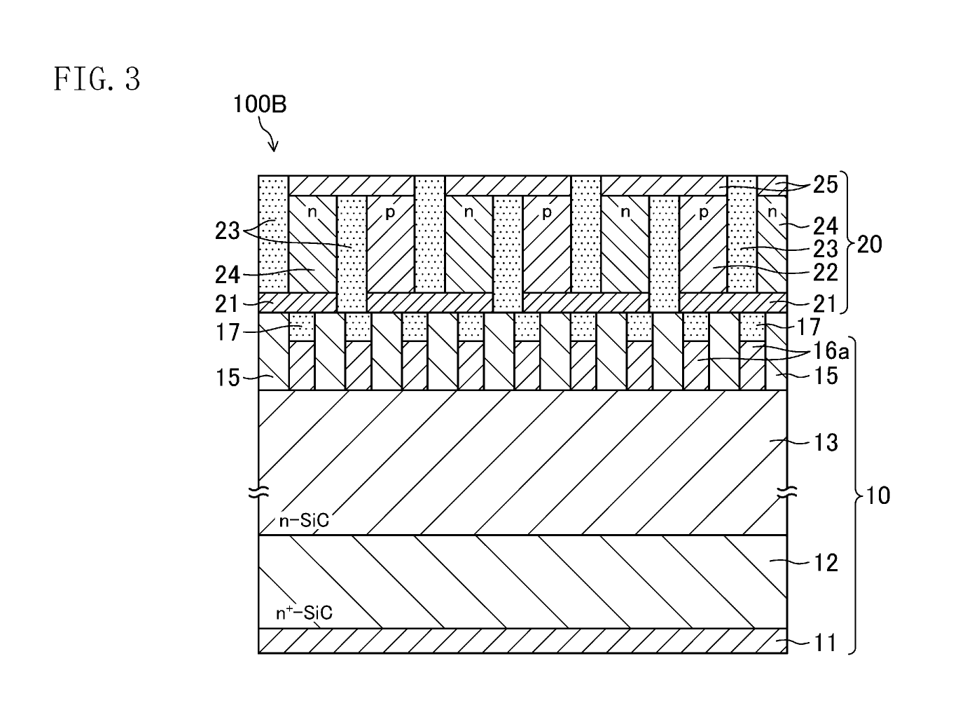

FIG. 3 illustrates a cross-sectional configuration of a main part of a semiconductor device of a second variation of the first embodiment of the present invention.

A semiconductor device 100B of the second variation includes a semiconductor element body portion 10 different from that of the first variation, but, except for this point, includes the same configurations as those of the first variation. Thus, also in FIG. 3, the same components as those of FIG. 2 are denoted with the same reference characters.

As illustrated in FIG. 3, the semiconductor element body portion 10 of the semiconductor device 100B of this variation corresponds to the JBS diode of the first variation from which the p⁺ regions 14a for improving the withstand voltage are omitted. Thus, the JBS diode of the second variation is a schottky-barrier diode (SBD). This is because the drift layer 13 is comprised of n-type SiC having a high withstand voltage, and thus the operation can be performed as a SBD without the p⁺ regions 14a.

Also in this variation, in addition to the thickness, etc. of the materials described in the first embodiment, the other applicable materials can be applied as well.

### Second Embodiment

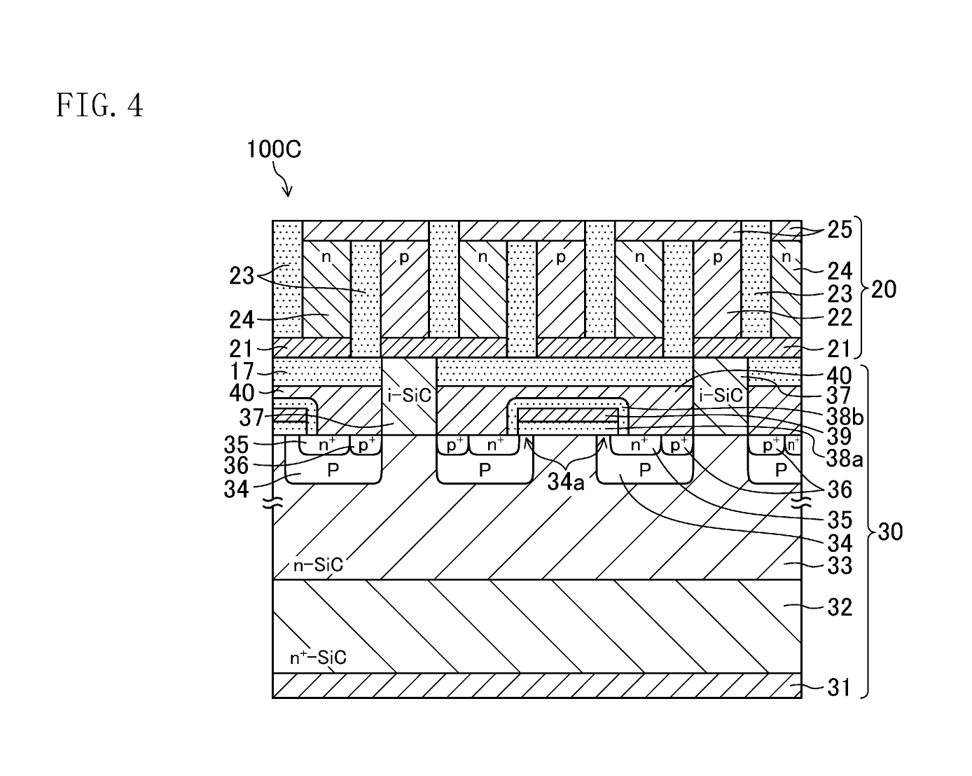

FIG. 4 illustrates a cross-sectional configuration of a main part of a semiconductor device of a second embodiment of the present invention.

As illustrated in FIG. 4, the semiconductor device 100C of this embodiment includes a semiconductor element body portion 30 and a heat absorbing element portion 20 integrally formed on the semiconductor element body portion 30.

The semiconductor device 100C of the second embodiment includes the semiconductor element body portion 30 different from that of the first embodiment, but, except for this point, includes the same configurations as those of the first embodiment. In the following descriptions, the same components as those of the first embodiment are denoted with the same reference characters.

As illustrated in FIG. 4, the semiconductor device 100C of this embodiment includes the semiconductor element body portion 30, which is a metal-oxide-semiconductor field-effect transistor (hereinafter also abbreviated as a MOSFET). The MOSFET constituting the semiconductor element body portion 30 includes a bulk layer (a contact layer) 32 comprised of n⁺-type SiC; a drift layer 33 regulating withstand voltage and comprised of n-type SiC epitaxially grown on the bulk layer 32; and a heat conducting layer 37 having insulation properties and comprised of i-type SiC epitaxially grown on the drift layer 33. Here, the impurity concentration of n⁺-type SiC may be approximately 1.0×10¹⁸ cm⁻³, and the impurity concentration of n-type SiC may be approximately 1.0×10¹⁶ cm⁻³, for example. The drift layer 33 may have a thickness of approximately 10 μm.

Gate electrodes 39 are each selectively formed via a gate insulation film 38a on a partial region (an electrode formation region) of a surface of the drift layer 33, the partial region being exposed from the heat conducting layer 37. The gate electrode 39 and the gate insulation film 38a are covered with an insulation film 38b. Here, the gate electrode 39 may be comprised of polysilicon (Poly-Si), and also may be comprised of polysilicon carbide (Poly-SiC), aluminum (Al), or copper (Cu), for example. The gate insulation film 38a may be comprised of silicon oxide (SiO₂), and also may be comprised of aluminum oxide (Al₂O₃), aluminum nitride (AlN), silicon nitride (Si₃N₄), boron nitride (BN), or diamond (C), for example.

Further, source electrodes 40 comprised of, e.g., nickel (Ni) are each formed on the drift layer 33 and on the electrode formation region between the heat conducting layers 37 to cover the associated insulation film 38b.

In an upper portion of the drift layer 33, p-type body layers 34 are each formed between the heat conducting layer 37 and an end portion of the gate insulation film 38a facing the heat conducting layer 37. Further, in an upper portion of the body layer 34, n⁺-type source layers 35 are each formed closer to the gate insulation film 38a. To improve the withstand voltage, p⁺ regions 36 are each formed adjacent to the source layer 35 and closer to the heat conducting layer 37. Each source layer 35 is in Ohmic contact with the source electrode 40 formed on the source layer 35. Note that a drain electrode 31 comprised of, e.g., nickel (Ni) is formed on a back surface of the bulk layer 32. The body layer 34, the source layer 35, and the p⁺ region 36 each can be formed by a publicly known lithography method and ion implantation method, for example. Here, the p-type impurity concentration of the body layer 34 may be approximately 1.0×10¹⁶ cm⁻³, and the n-type impurity concentration of the source layer 35 may be approximately 1.0×10²⁰ cm⁻³, for example.

In the MOSFET, a predetermined voltage is applied to the gate electrode 39 such that a n-type channel region 34a (an inversion layer) is formed at a boundary portion between the p-type body layer 34 and the gate insulation film 38a. As a result, an operation current flows though the drain electrode 31, the bulk layer 32, the drift layer 33, the channel region 34a, the source layer 35, and the source electrode 40 in this order. In this current path, the channel region 34a has a large channel resistance, and the drift layer 33 has a large drift resistance. Thus, the ratio of the Joule heat caused by the channel resistance and the drift resistance is high to the total calorific value of the semiconductor element body portion 30.

Again, similarly to the semiconductor device 100 of the first embodiment, as long as the heat absorbing element portion 20 covers 10% or more of the area of a heat source of the semiconductor element body portion 30, the advantage of the present invention can be reliably obtained. The heat source of the semiconductor element body portion 30 mainly refers to the sum of regions in plan view of a region including the plurality of channel regions 34a and the drift layer 33

—Advantage—

As described above, according to this embodiment, the heat absorbing element portion 20 of the thin-film Peltier type is integrally formed on the semiconductor element body portion 30 configured as a MOSFET. The lower electrode 21 of the heat absorbing element portion 20 is directly connected to the heat conducting layer 37 having insulation properties and being the epitaxial growth part of the semiconductor element body portion 30. This significantly reduces the thermal resistance between the semiconductor element body portion 30 and the heat absorbing element portion 20.

### Third Embodiment

One example of a method for manufacturing a semiconductor device of a third embodiment of the present invention will be described below with reference to the drawings. FIGS. 5 to 18 illustrate cross-sectional configurations in order of steps of the method for manufacturing a main part of the semiconductor device of the third embodiment.

First, FIG. 18 illustrates that a semiconductor element body portion 10 of the semiconductor device 100D of the third embodiment is configured as a drift layer 13 of which a bulk layer is comprised of n-type SiC. A heat conducting layer 15 having insulation properties and comprised of i-type SiC is epitaxial grown to be formed on a +c plane of the drift layer 13. A heat absorbing element portion 20 is not arranged in an electrode formation region 10a in the drift layer 13, the electrode formation region 10a being a region where the cathode electrode 16 of the semiconductor element body portion 10 is formed.

As illustrated in FIG. 5, the method for manufacturing the semiconductor device 100D of this embodiment includes, first, preparing a substrate (the drift layer 13) having the +c plane (hereinafter referred to as a front surface) on which a SiC layer (the heat conducting layer 15) is epitaxially grown, the SiC layer having a thickness of approximately 1 μm and having insulation properties; and then forming a nickel (Ni) film on a −c plane (hereinafter referred to as a back surface) of the prepared substrate, the nickel (Ni) film being to be an anode electrode 11. Specifically, the substrate is washed with SH (sulfuric acid hydrogen peroxide solution), and then the Ni film having a thickness of approximately 100 nm is formed on the back surface by the sputtering method. Then, the substrate having the Ni film formed thereon is introduced into a rapid thermal annealing (RTA) furnace, and subjected to heat treatment at a temperature of 1000° C. for two minutes. By this heat treatment, the Ni film formed is converted into silicide. That is, the anode electrode 11 comprised of nickel silicide (NiSiₓ) is obtained. Note that the substrate herein may be a wafer substrate which can be divided into a plurality of chips, or may be a divided substrate forming part of a chip.

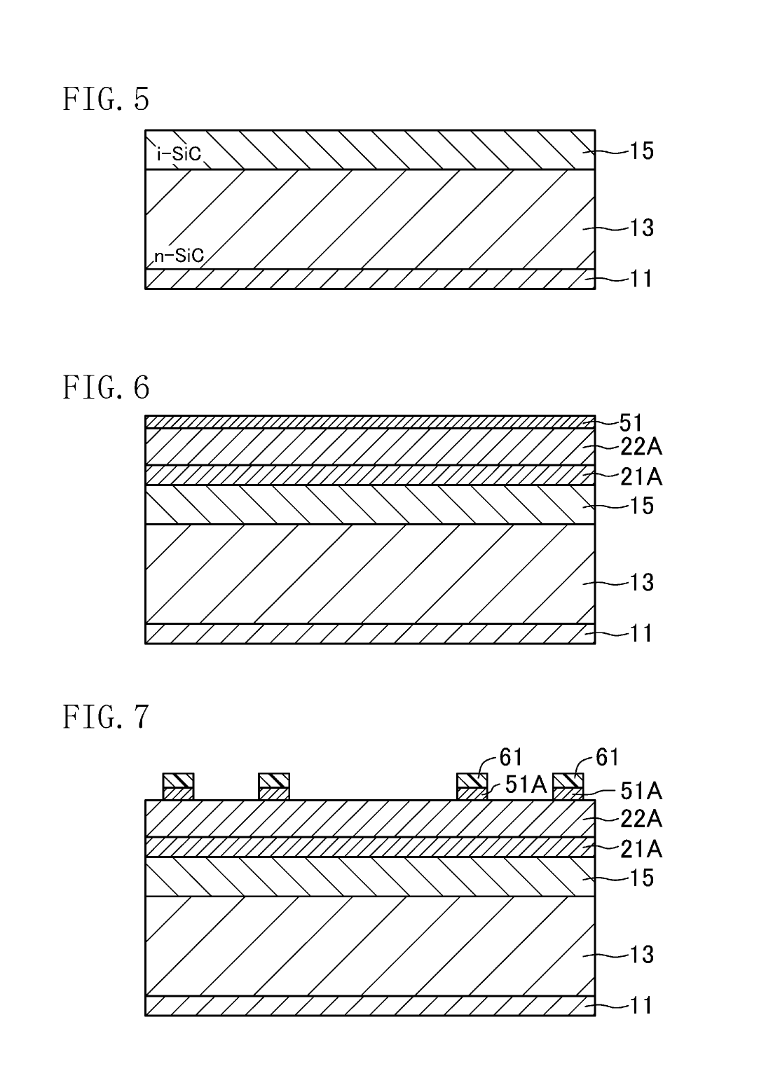

Next, as illustrated in FIG. 6, for example, a lower electrode formation film 21A comprised of nickel and having a thickness of approximately 450 nm, a p-type silicon layer 22A having a thickness of approximately 1.2 μm, and a first sacrificial film 51 comprised of nickel and having a thickness of approximately 200 nm are formed in order on or above the heat conducting layer 15. The lower electrode formation film 21A and the first sacrificial film 51 can be formed by the sputtering method, for example. The p-type silicon layer 22A can be formed by the chemical vapor deposition (CVD) method or the sputtering method, for example.

Next, by the lithography method, a first mask pattern 61 is formed on the first sacrificial film 51 to obtain dotted p-type silicon layers 22 from the p-type silicon layer 22A. Then, the first mask pattern 61 formed is used as a mask, and hydrochloric acid hydrogen peroxide solution is used to wet-etch the first sacrificial film 51. Consequently, as illustrated in FIG. 7, the first mask film 51A is formed from the first sacrificial film 51. The hydrochloric acid hydrogen peroxide solution used herein is a mixture containing concentrated hydrochloric acid, hydrogen peroxide solution, and pure water at a volume ratio of e.g., 1:1:10. After the pure water is added to the hydrogen peroxide solution, the concentrated hydrochloric acid is added.

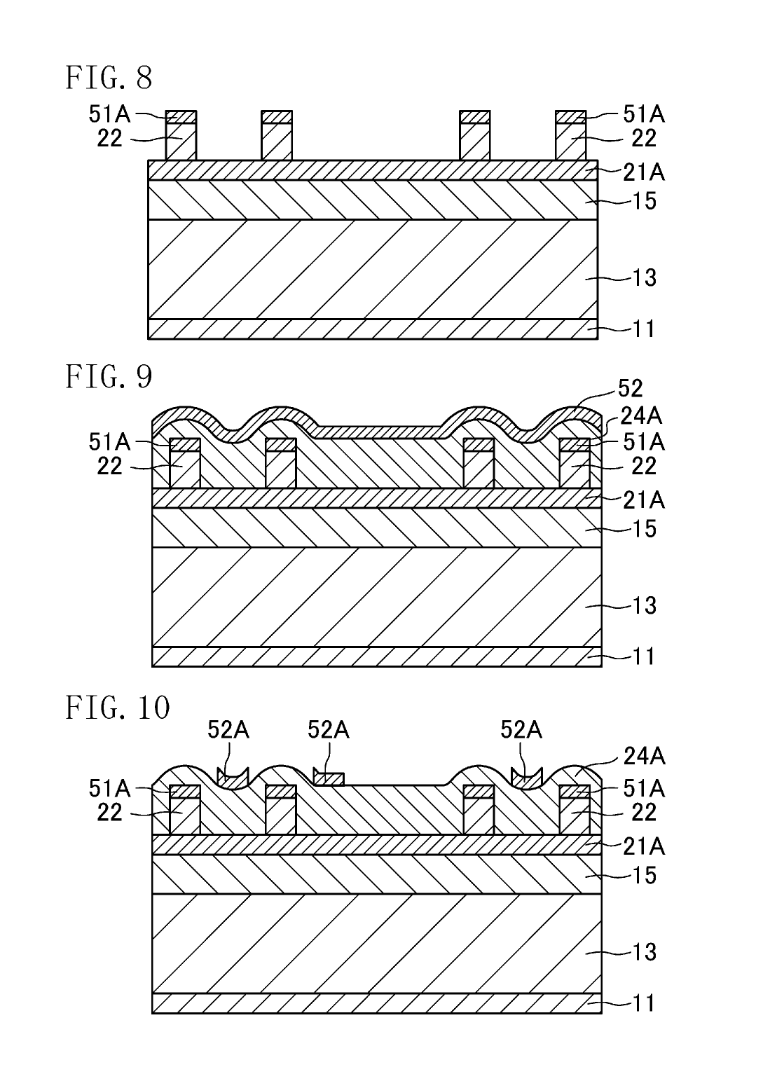

Next, as illustrated in FIG. 8, by dry-etching with the first mask film 51A serving as a mask, a plurality of p-type silicon layers 22 having a dotted block pattern are obtained. For the dry-etching, inductively coupled plasma (ICP) with a reactive gas which is a mixed gas of chlorine (Cl₂) and hydrogen bromide (HBr) is used. An example of plasma etching conditions includes a substrate temperature of −15° C., a pressure of approximately 0.133 Pa in a reactor, ICP output of 400 W, and a substrate bias voltage of 190 V. The flow rate of Cl₂ gas is 40 ml/min (0° C., 1 atm), and the flow rate of HBr gas is 20 ml/min (0° C., 1 atm). Note that the etching conditions are not limited thereto.

Next, in the steps illustrated in FIGS. 9 to 11, a plurality of n-type silicon layers 24 having a dotted block pattern are formed.

Specifically, as illustrated in FIG. 9, a n-type silicon layer 24A and a second sacrificial film 52 comprised of nickel (Ni) are formed in order on or above the lower electrode formation film 21A including the p-type silicon layers 22. Again, the n-type silicon layer 24A can be formed by the CVD method or the sputtering method, and the second sacrificial film 52 can be formed by the sputtering method.

Next, as illustrated in FIG. 10, similarly to the step illustrated in FIG. 7, hydrochloric acid hydrogen peroxide solution is used to form second mask films 52A from the second sacrificial film 52 to obtain the dotted n-type silicon layers 24. Then, the surfaces of the second mask films 52A may be cleaned.

Next, as illustrated in FIG. 11, similarly to the step illustrated in FIG. 8, the second mask film 52A is used as a mask. By ICP etching with a mixed gas of Cl₂ and HBr, the plurality of n-type silicon layers 24 having a dotted block pattern are obtained from the n-type silicon layer 24A. Note that no particular order of formation of the p-type silicon layers 22 and the n-type silicon layers 24 having a dotted pattern is required.

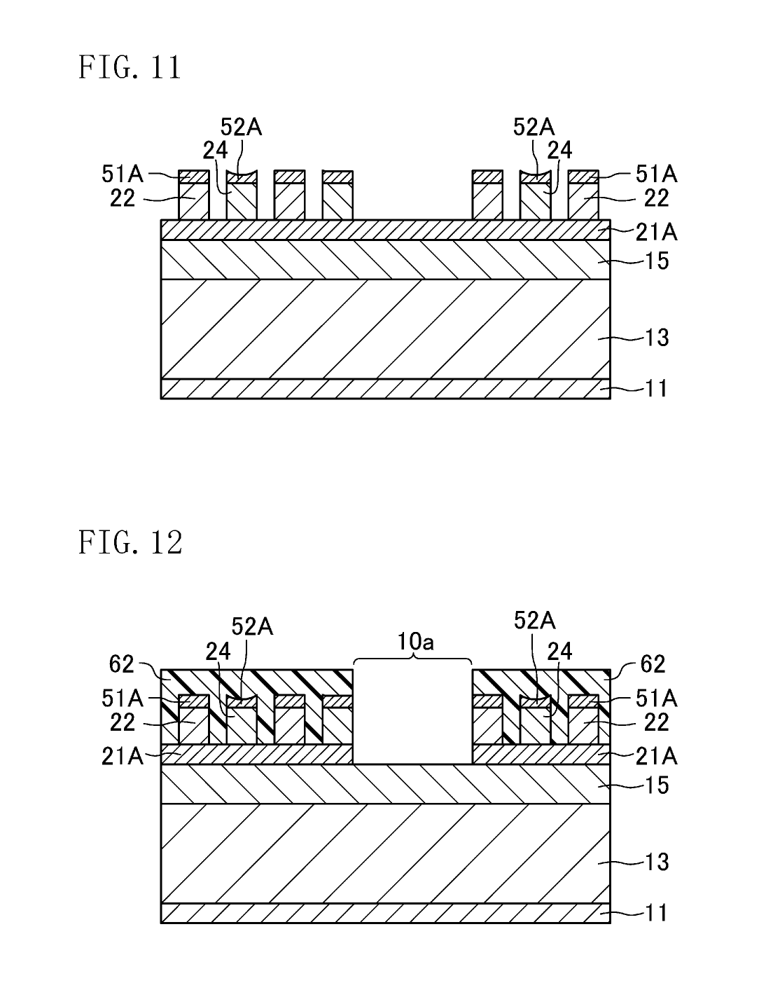

Next, by the lithography method, a second mask pattern 62 including an electrode formation region 10a for a SBD as an opening pattern is formed on the lower electrode formation film 21A including the p-type silicon layers 22 and the n-type silicon layers 24. Then, the second mask pattern 62 formed is used as a mask, and hydrochloric acid hydrogen peroxide solution is used to etch the lower electrode formation film 21A. Then, as illustrated in FIG. 12, a portion, of the lower electrode formation film 21A, contained in the electrode formation region 10a is removed.

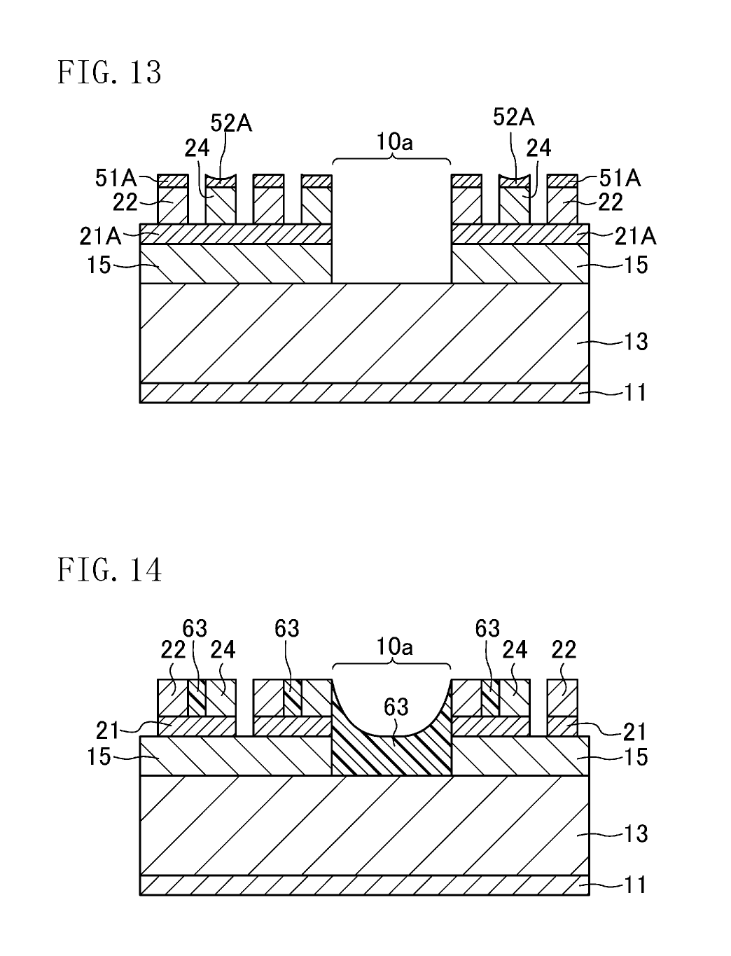

Next, as illustrated in FIG. 13, the second mask pattern 62 is removed. Subsequently, using the first mask film 51A, the second mask film 52A, and the lower electrode formation film 21A as hard masks, ICP etching of the heat conducting layer 15 is performed in a manner similar to the step illustrated in FIG. 11, so that the electrode formation region 10a of the drift layer 13 is exposed. Here, the heat conducting layer 15 comprised of i-type SiC has a thickness of 1 μm. Thus, the value of a substrate bias voltage of ICP etching is switched to, e.g., 450 V from 190 V for the silicon layer. In this embodiment, as described above, the lower electrode formation film 21A has a thickness of 450 nm, and the mask films 51A, 52A have a thickness of 200 nm. In consideration of decrease in the hard masks, the thicknesses of the hard masks can be changed as appropriate. For example, in this embodiment, the lower electrode formation film 21A may have a thickness of approximately 700 nm at most, and the mask films 51A, 52A may have a thickness of approximately 400 nm at most.

Next, as illustrated in FIG. 14, by the lithography method, a third mask pattern 63 having a lower electrode formation pattern is formed on the lower electrode formation film 21A including the electrode formation region 10a of the drift layer 13. Then, the third mask pattern 63 formed is used as a mask, and hydrochloric acid hydrogen peroxide solution is used for etching to form a plurality of lower electrodes 21 from the lower electrode formation film 21A.

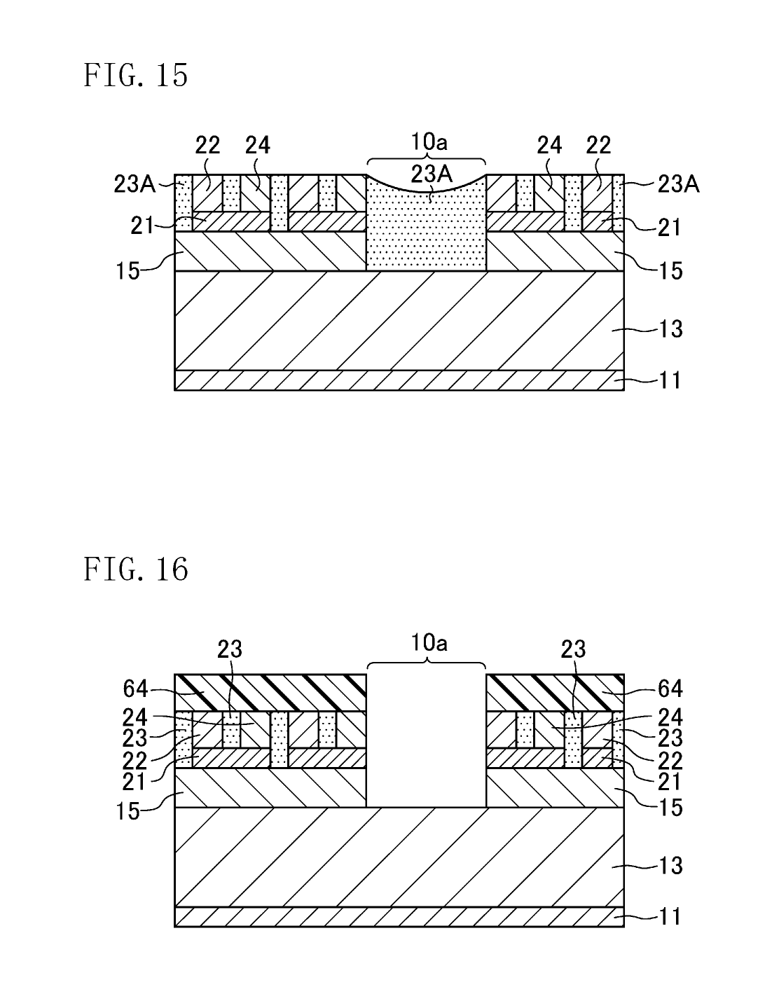

Next, as illustrated in FIG. 15, the third mask pattern 63 is removed. Then, by the spin coating method, silicon oxide (SiO₂) dispersion is applied onto the entire surface of the substrate. Then, a pre-curing treatment at 180° C. for 30 minutes in air and a main curing treatment at a temperature of 400° C. for 30 minutes in nitrogen are sequentially performed to form an insulation formation film 23A. Note that, before formation of the insulation formation film 23A, a heat treatment may be performed with, e.g., bis(trimethylsilyl)amine (HMDS) to conduct hydrophobization of surfaces of the silicon layers 22, 24 and a surface of the electrode formation region 10a in the drift layer 13. Specifically, it is suitable to heat-treat the spin-coated HMDS in air at a temperature of 180° C. for 5 minutes.

Next, by the lithography method, a fourth mask pattern 64 having an opening pattern in the electrode formation region 10a on the insulation formation film 23A is formed. Then, the insulation formation film 23A is wet-etched with buffered hydrofluoric acid (BHF), so that the electrode formation region 10a in the drift layer 13 is exposed again, as illustrated in FIG. 16.

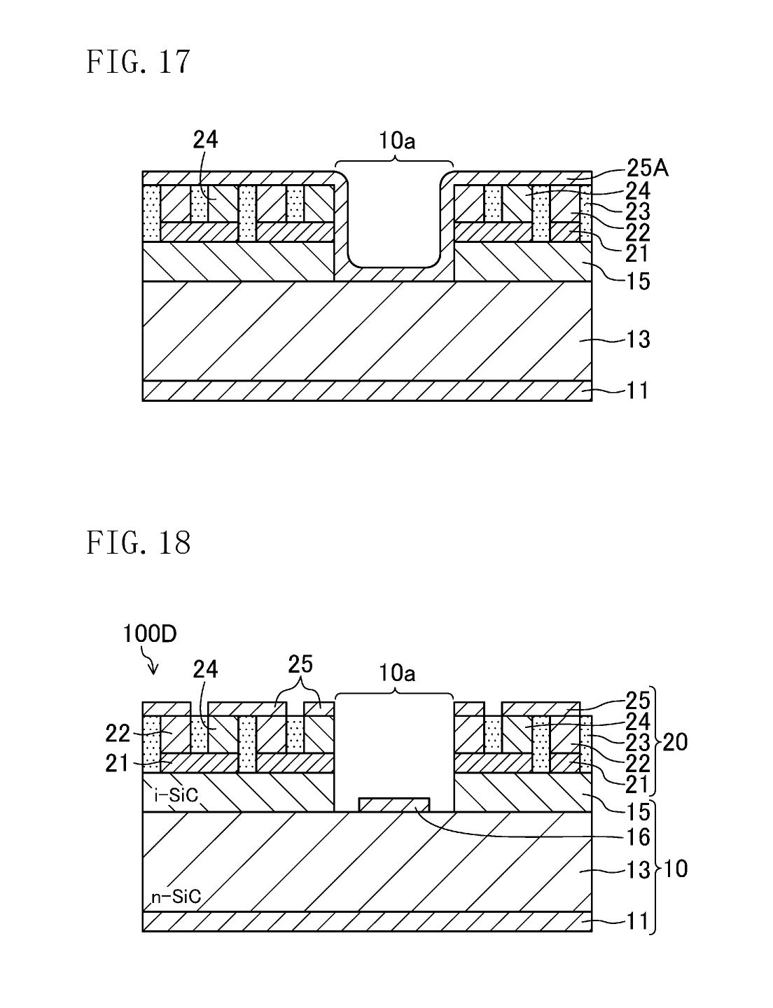

Next, as illustrated in FIG. 17, by the sputtering method, an electrode formation film 25A of nickel (Ni) is formed such that the electrode formation film 25A formed has a thickness of, e.g., 200 nm in at least the electrode formation region 10A of the drift layer 13. Then, the surface of the electrode formation film 25A may be cleaned.

Next, as illustrated in FIG. 18, by the lithography method, the electrode formation film 25A is wet-etched with hydrochloric acid hydrogen peroxide solution by using a mask pattern (not shown) including an upper electrode pattern of the Peltier element and an electrode pattern of the SBD, thereby forming the plurality of upper electrodes 25 of the Peltier element and the cathode electrode 16 of the SBD from the electrode formation film 25A. As such, the semiconductor device 100D of this embodiment is obtained.

—Advantage—

As described above, according to this embodiment, for example, the semiconductor device 100D including the semiconductor element body portion 10 and the heat absorbing element portion 20 can be reliably formed, the semiconductor element body portion 10 comprised of the SBD element including the heat conducting layer 15 having insulation properties (i-type SiC) and epitaxially grown on the drift layer 13 which is a bulk portion of silicon carbide (SiC), and the heat absorbing element portion 20 comprised of the thin-film Peltier element of silicon (Si), and directly formed on, i.e., thermally coupled to the heat conducting layer 15.

### Other Embodiments

In the embodiments described above and the variations thereof, the heat conducting layers 15, 37 having insulation properties are comprised of i-type SiC. Instead, any of them may be comprised of silicon (Si), gallium nitride (GaN), aluminum nitride (AlN), silicon nitride (SiNx), zinc oxide (ZnO), C (diamond), boron nitride (BN), or gallium oxide (Ga₂O₃), each having insulation properties. Here, each material preferably has a thermal conductivity of 5 W/mK or more, and an electric resistivity of 10⁸ Ωcm or more.

The heat conducting layers 15, 37 comprised of the above materials are preferably in thermal and continuous contact with, and integrated with, the semiconductor element body portions 10, 30.

The heat conducting layers comprised of the above materials is preferably formed through epitaxial growth on the surface of the semiconductor material forming part of the semiconductor device body portions 10, 30.

Specifically, as the semiconductor material forming part of the semiconductor element body portions 10, 30, silicon (Si), gallium nitride (GaN), aluminum nitride (AlN), silicon nitride (SiNx), zinc oxide (ZnO), C (diamond), boron nitride (BN), or gallium oxide (Ga₂O₃) can be used.

A heat insulating layer may be provided in a heat generating region (e.g., the channel region 34a in FIG. 4) having a relatively narrow width in the semiconductor element body portions 10, 30, and, for example, along a longitudinal direction of the heat conducting layer 37 in FIG. 4, so that the heat insulating layer insulate heat in the surrounding area. In this case, the heat insulating layer preferably has a thermal conductivity of 0.5 W/mK or less.

### Example

One example of the heat absorbing element of the present invention will be described below with reference to the drawings.

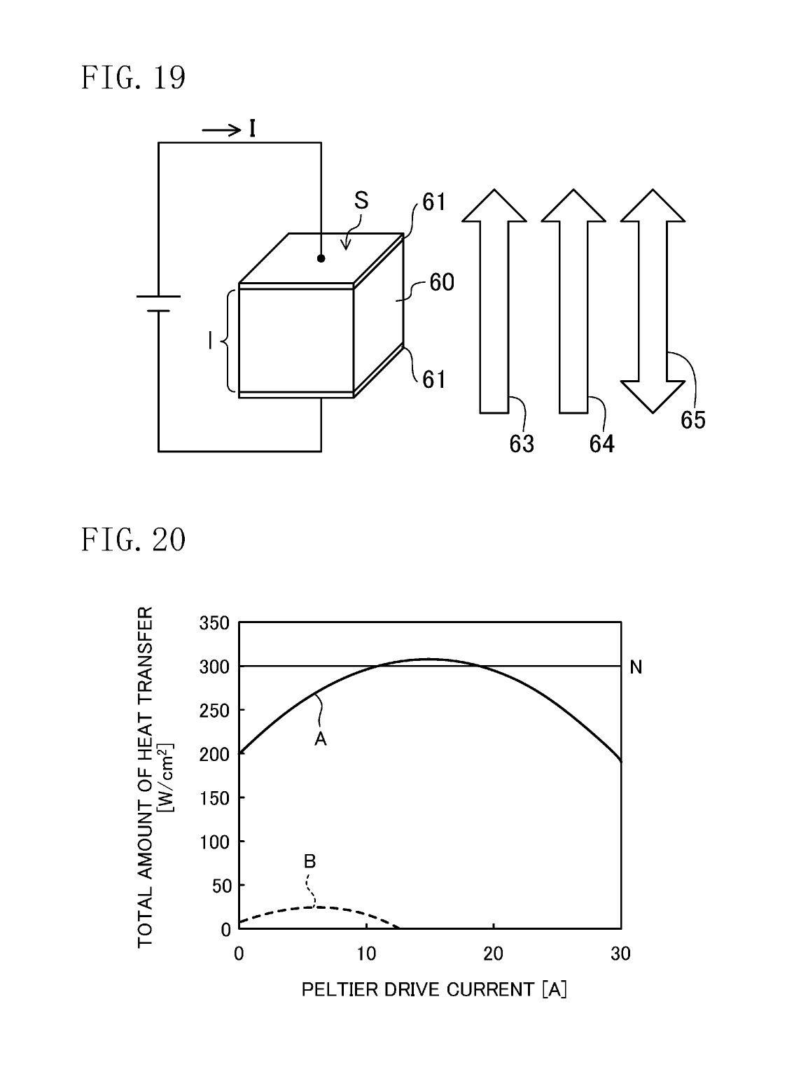

As illustrated in FIG. 19, a single unit of a Peltier element 60, which is the heat absorbing element of this example, has a size represented by plane area S×height (thickness) 1=1 mm²×1 mm=1 mm³. In FIG. 19, the Peltier element 60 includes a front surface and a back surface, each provided with a metal electrode 61 comprised of, e.g., nickel. The front surface is connected to a positive electrode of a power supply, and the back surface is connected to a negative electrode of the power supply such that current I flows therebetween. In this case, the arrow 63 represents heat transfer caused by Peltier effect. The arrow 64 represents heat transfer caused by heat conduction. The arrow 65 represents heat generation caused by Joule heat.

Here, the front and back surfaces of the Peltier element 60 have a temperature difference of 40° C. For example, the following situation can be assumed: the front surface is connected with a cooler through which a cooling medium having a temperature of 80° C. flows and the back surface is connected with a power device having a temperature of 120° C. or less. An ambient environment temperature is 295 K (22° C.: room temperature), and an electric resistivity is 1×10⁻⁵ Ωm.

The heat absorbing performance of the Peltier element is typically represented by [Formula 1] shown below.

Qₒᵤₜ=αₑT_{cj}I−(½)RI²−KΔTⱼ [Formula 1]

where R=ρ(S/l), κ=κ(l/S)

Here, Qₒᵤₜ represents the total amount of heat transfer. α represents a Seebeck coefficient. T represents room temperature. I represents a current (a Peltier drive current). ΔT represents a temperature difference between the front surface and the back surface. ρ represents an electric resistivity. S represents an area of a single Peltier element. l represents a thickness of a single Peltier element. κ represents a thermal conductivity. [Formula 1] consists of a first term representative of a Peltier effect, a second term representative of Joule heat, and a third term representative of heat conduction.

The following [Table 1] shows a list of numeric values for use in calculation of bismuth tellurium (Bi₂Te₃) used typically; and silicon (Si), silicon carbide (SiC), gallium nitride (GaN), aluminum nitride (AlN), boron nitride (BN), and diamond (C) usable for the present invention.

TABLE 1

| | | Present Invention | | | | | | |
|---|---|---|---|---|---|---|---|---|
| | Bi₂Te₃ | (Lower Limit Value) | Si | SiC | GaN | AlN | BN | Diamond |
| Seebeck Coefficient (α) [V/K] | 2.0 × 10⁻⁴ | 3.0 × 10⁻⁴ | 1.0 × 10⁻³ | 3.0 × 10⁻⁴ | 5.0 × 10⁻⁵ | 5.8 × 10⁻⁴ | 5.0 ×10⁻⁴ | 5.7 × 10⁻⁴ |
| Thermal Conductivity (κ) [W/mK] | 1.5 | 50 | 150 | 490 | 130 | 319 | 1300 | 2000 |
| Electric Resistivity (ρ) [Ωm] | 1.5 × 10⁻⁵ | ← | ← | ← | ← | ← | ← | ← |
| Area of Single Unit (S) [m²] | 1.0 × 10⁻⁵ | ← | ← | ← | ← | ← | ← | ← |
| Thickness of Single Unit (l) [m] | 1.0 × 10⁻³ | ← | ← | ← | ← | ← | ← | ← |
| Room Temperature T [K] | 295 | ← | ← | ← | ← | ← | ← | ← |
| Temprature Difference between | 40 | ← | ← | ← | ← | ← | ← | ← |
| Front and Back Surfaces (ΔT) [K] | | | | | | | | |
| Maximum Amount of Heat | 23.4 | 300 | 660 | 774 | 300 | 625 | 2059 | 3141 |
| Absorbtion (Q_{incl}) [W/cm²] | | | | | | | | |

Next, based on the result of the calculation of the numeric values of [Table 1] according to [Formula 1], the numeric values of the bismuth tellurium used typically and the lower limit values of this example (the present invention) are graphed in FIG. 20 for comparison. In this example, the minimum value (referred to as needs (N)) of a desired total amount of heat transfer (the amount of heat absorption) is set to be 300 W/cm² in consideration of the application of the Peltier element of this example. This value is the needs based on a calorific value of a power device, for example.

As illustrated in FIG. 20, in the graph A representative of the lower limit value of this example (where the Seebeck coefficient is 300 μV/K or more, and the thermal conductivity is 50 W/mK or more), the maximum amount of heat absorption is 308.8 W/cm², which satisfies the above needs. On the other hand, in the graph B representative of the typical Peltier element with bismuth tellurium, the maximum amount of heat absorption is only 23.4 W/cm², and cannot satisfy the needs.

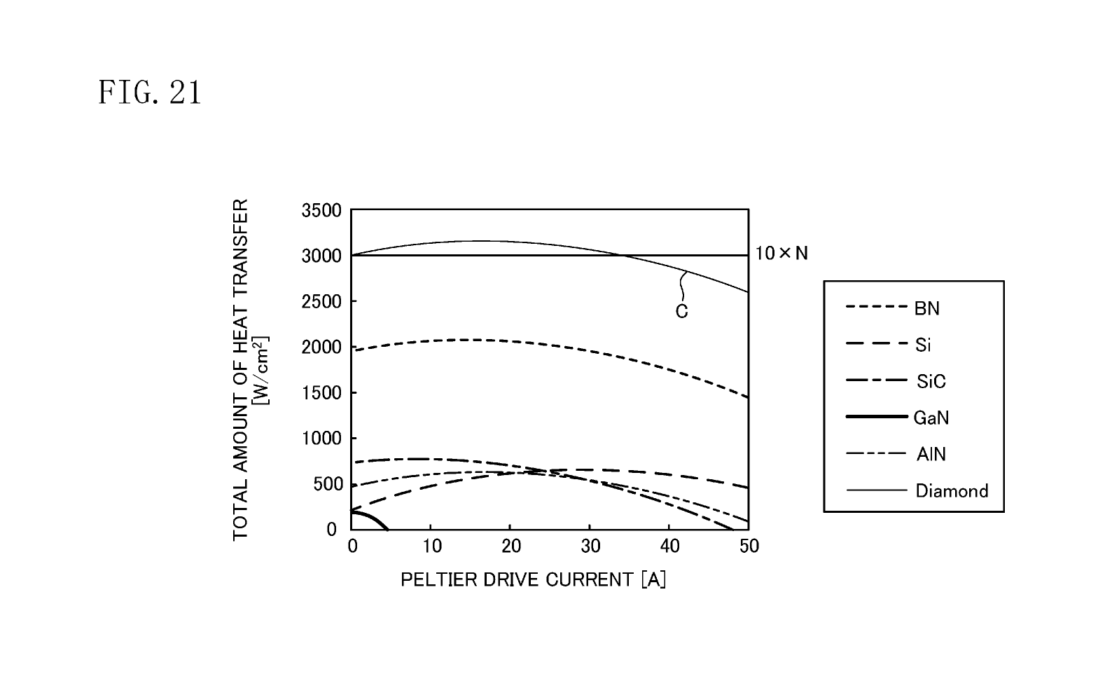

FIG. 21 shows graphs determined by calculation values for the materials (except for bismuth tellurium) listed in [Table 1], with a temperature difference ΔT between the front the back surfaces at 40° C. As illustrated in FIG. 21, in the graph C for the Peltier element comprised of diamond, the maximum amount of heat absorption is approximately 3100 W/cm². Thus, if the Peltier element covers 10% or more of 3000 W/cm² which is ten times of the needs N, i.e., in this example, a region of 10% or more of the surface area of the power device (the heat source), the value of the needs N can be satisfied.

### INDUSTRIAL APPLICABILITY

The present invention relating to a heat absorbing element, a semiconductor device having the same, and a method for manufacturing the heat absorbing element can provide reduction in thermal resistance between the semiconductor element and the heat absorbing element. In addition to motor vehicles (HV, HEV etc.) having an inverter containing such a semiconductor device, the present invention is applicable to electric power generation systems, transmission/distribution systems (smart grids etc.); transportations except for automobiles (railways, ships, aircrafts, etc.); industry machinery (FA equipment, elevators, etc.); IT equipment (personal computers, cellular phones, etc.); consumer/home appliances (air conditioners, FPD, AV equipment, etc.); and the manufacturing techniques thereof.

### DESCRIPTION OF REFERENCE CHARACTERS

10 Semiconductor Element Body Portion (Semiconductor Element/Power Semiconductor Element)
10a Electrode Formation Region
15 Heat Conducting Layer (Electrical Insulator)
16 Cathode Electrode (Electrode of Semiconductor Element)
16a Cathode Electrode
20 Heat Absorbing Element Portion (Heat Absorbing Element/Peltier Element)
21A Lower Electrode Formation Film (Lower Metal Film)
21 Lower Electrode
22 P-type Silicon Layer (P-type Semiconductor Layer/First Conductivity Type Semiconductor Block)
22A P-type Silicon Layer (First Conductivity Type Semiconductor Layer)
24 N-type Silicon Layer (N-type Semiconductor Layer/Second Conductivity Type Semiconductor Block)
24A N-type Silicon Layer (Second Conductivity Type Semiconductor Layer)
25 Upper Electrode
25A Electrode Formation Film (Upper Metal Film)
30 Semiconductor Element Body Portion (Semiconductor Element/Power Semiconductor Element)
51 First Sacrificial Film (First Metal Sacrificial Film)
51A First Mask Film (First Metal Mask Film)
52 Second Sacrificial Film (Second Metal Sacrificial Film)
52A Second Mask Film (Second Metal Mask Film)
60 Peltier Element
100, 100A, 100B, 100C, 100D Semiconductor Device

1. A heat absorbing element of a thin-film Peltier type thermally connected with a surface of a semiconductor element through an electrical insulator, wherein
the heat absorbing element is comprised of a substance having a bulk thermal conductivity of 50 W/mK or more and a Seebeck coefficient of 300 μV/K or more.

2. The heat absorbing element of claim 1, wherein
the substance is any one of silicon, silicon carbide, gallium nitride, aluminum nitride, boron nitride, or diamond.

3. The heat absorbing element of claim 1, wherein
the substance is silicon.

4. The heat absorbing element of claim 1, wherein
the substance constitutes a p-type or n-type semiconductor layer, and
the p-type semiconductor layer and the n-type semiconductor layer are arranged parallel to the semiconductor element and the electrical insulator.

5. The heat absorbing element of claim 1, wherein
the heat absorbing element is directly formed on, and thermally coupled with, a heat exhaust side of the semiconductor element.

6. The heat absorbing element of claim 1, wherein
the heat absorbing element covers 10% or more of an area of a heat source in the semiconductor element.

7. A semiconductor device, comprising the heat absorbing element of claim 1.

8. The semiconductor device of claim 7, wherein
the semiconductor element is a power semiconductor element.

9. The semiconductor device of claim 7, wherein
the semiconductor element is a SiC power semiconductor element of which a material is silicon carbide.

10. A method for manufacturing a heat absorbing element of a thin-film Peltier type thermally connected with a surface of a semiconductor element through an electrical insulator,
the method comprising:
forming a lower metal film, a first conductivity type semiconductor layer, and a first metal sacrificial film in order on the semiconductor element through the electrical insulator;
forming a first metal mask film for patterning the first conductivity type semiconductor layer from the first metal sacrificial film, and using the first metal mask film formed, patterning the first conductivity type semiconductor layer so as to form a plurality of first conductivity type semiconductor blocks from the first conductivity type semiconductor layer;
forming a second conductivity type semiconductor layer and a second metal sacrificial film in order on the lower metal film including the first conductivity type semiconductor block;
forming a second metal mask film for patterning the second conductivity type semiconductor layer from the second metal sacrificial film, and using the second metal mask film formed, patterning the second conductivity type semiconductor layer so as to form a plurality of second conductivity type semiconductor blocks from the second conductivity type semiconductor layer;
selectively etching, by a lithography method, an electrode formation region of the semiconductor element in the lower metal film so as to expose the semiconductor element;
selectively etching, by a lithography method, a portion between the first conductivity type semiconductor block and the second conductivity type semiconductor block in the lower metal film so as to form a plurality of lower electrodes from the lower metal film;
selectively forming an insulation film on a portion between the semiconductor blocks and on a portion between the lower electrodes, followed by forming an upper metal film on the semiconductor blocks and on an exposed portion of the semiconductor element; and
selectively etching, by a lithography method, the upper metal film so as to form an upper electrode and an electrode of the semiconductor element from the upper metal film.

11. The method of claim 10, wherein
the first conductivity type semiconductor layer and the second conductivity type semiconductor layer are each comprised of any one of silicon, silicon carbide, gallium nitride, aluminum nitride, boron nitride, or diamond.

12. The method of claim 10, wherein
the lower metal film, the first metal sacrificial film, the second metal sacrificial film, and the upper metal film are comprised of nickel, and
at least one of the lower metal film, the first metal sacrificial film, the second metal sacrificial film, or the upper metal film is patterned by wet-etching with an etchant which is a mixture of concentrated hydrochloric acid, concentrated hydrogen peroxide solution, and pure water.

13. The method of claim 10, wherein
the first metal sacrificial film and the second metal sacrificial film are comprised of nickel,
the first conductivity type semiconductor layer and the second conductivity type semiconductor layer are comprised of silicon, and
the forming the first conductivity type semiconductor blocks and the forming the second conductivity type semiconductor blocks are carried out by dry-etching with chlorine and hydrogen bromide.

14. The method of claim 10, wherein
the semiconductor element is a power semiconductor element.

15. The method of claim 10, wherein
the semiconductor element is a SiC power semiconductor element of which a material is silicon carbide.
